(19) United States
(12) Patent Application Publication
(10) Pub. No.: US 2019/0036054 A1
(43) Pub. Date: Jan. 31, 2019

(54) CATHODE LAYER STACK FOR SEMI-TRANSPARENT OPV DEVICES

(71) Applicant: Cambridge Display Technology Limited, Godmanchester (GB)

(72) Inventors: Philip Benzie, Limited (GB); William Young, Godmanchester (GB)

(73) Assignee: Cambridge Display Technology Limited, Godmanchester (GB)

(21) Appl. No.: 16/071,878

(22) PCT Filed: Jan. 18, 2017
(86) PCT No.: PCT/EP2017/051006

§ 371 Date: Jul. 20, 2018

(30) Foreign Application Priority Data
Jan. 20, 2016 (GB) 1601055.5

(51) Int. Cl. H01L 51/44; H01L 51/52; H01L 51/00

(52) U.S. Cl. CPC H01L 51/442; H01L 51/5253; H01L 51/5234; H01L 51/0047; H01L 51/5275

(57) ABSTRACT

The invention relates to a cathode layer stack used for semi-transparent organic photovoltaic devices with improved transmission of light in the visible wavelength range and excellent photovoltaic response. The cathode layer stack comprises an organic buffer layer (14b) deposited over a semi-transparent metal cathode (14c) and a silicon dioxide (SiO₂) layer (14a) provided over the organic buffer layer (14b), wherein the refractive index of the silicon dioxide layer is lower than the refractive index of the buffer layer, and wherein the thickness of the silicon dioxide layer is less than 100 nm. In further embodiments, methods of manufacturing the cathode layer stack, organic photovoltaic devices comprising said cathode layer stack and uses thereof are described.

### FIELD OF INVENTION

This invention relates to a cathode layer stack used for semi-transparent organic photovoltaic devices with improved transmission of light in the visible wavelength range and excellent photovoltaic response and methods of manufacturing the same. In addition, the present invention relates to organic photovoltaic devices comprising said cathode layer stack and uses thereof.

### BACKGROUND OF THE INVENTION

There has been increased interest in organic photovoltaic (OPV) devices as alternatives to inorganic material-based photovoltaic devices since they may be utilized to manufacture large area and flexible solar modules at relatively low costs. One exemplary application of OPV devices is the use as building-integrated photovoltaics or building-applied photovoltaics in building exterior such as skylights, windows, roofs, curtain walls or façades.

Most OPV devices include a p-n junction as a photoactive layer which is typically sandwiched between a transparent electrode and a metal electrode and which is prepared by film deposition of a donor/acceptor blend from solution and enables the device to convert incident radiation into electrical current. Typical examples of p-type materials are conjugated organic oligomers or polymers, whereas fullerene and fullerene derivatives play an important role as n-type materials. In the recent years, emphasis has been laid on improving the power conversion efficiencies (PCE) of OPV devices by developing novel p- and n-type materials and controlling the morphology of the photoactive layer.

For use in window glass, OPV devices require a visible light transmission of more than 50% while maintaining a satisfactory PCE. In this context, the choice and thickness of the semi-transparent cathode is critical. For example, when using a thin evaporated silver layer as a semi-transparent cathode, the layer must have a sufficient thickness in order to maintain good conduction within the film and thereby maintain a high PCE. However, increasing the layer thickness leads to a maximum transmission for the contact layer which can be less than that required for semi-transparent device application, so that OPV devices with semi-transparent metal cathodes generally tend to have low transmission properties.

Therefore, it would be desirable to provide a cathode layer stack which allows maximizing the transmission of OPV devices without reducing the PCE.

It is known to provide organic electroluminescent elements with a cathode stack comprising a semi-transparent thin film metal cathode, a sputtered moisture-protective or oxidation-resistant layer composed of an inorganic oxide and an evaporated organic buffer layer which avoids sputtering damage of the underlying layers due to the bombardment effect of the energetic particles and/or high temperature (see e.g. US 2007/0228942 A1, US 2012/0211782 A1 or US 2012/0007068 A1).

However, these publications are concerned with the provision of organic electronic devices with improved protection function and do not address the problem of maximizing the transmission of OPV devices without reducing the PCE.

### SUMMARY OF THE INVENTION

The present invention solves these objects with the subject matter of the claims as defined herein. The advantages of the present invention will be further explained in detail in the section below and further advantages will become apparent to the skilled artisan upon consideration of the invention disclosure.

Generally speaking, the present invention relates to a semi-transparent cathode layer stack for a organic photovoltaic device comprising an organic buffer layer deposited over a semi-transparent metal cathode and a silicon dioxide (SiO₂) layer provided over the organic buffer layer, wherein the refractive index of the silicon dioxide layer is lower than the refractive index of the buffer layer, and wherein the thickness of the silicon dioxide layer is less than 100 nm.

The present inventors surprisingly found that by using said semi-transparent cathode layer stack in an OPV device, excellent transmission properties may be achieved without impairing the power conversion efficiency of the device.

Another aspect of the present invention is a method of manufacturing the cathode layer stack.

In a further aspect, the present invention relates to an organic photovoltaic device comprising the above-defined semi-transparent cathode layer stack and to building material comprising the aforementioned organic photovoltaic device.

Another aspect of the present invention is the use of the aforementioned organic photovoltaic device in building-integrated photovoltaics or building-applied photovoltaics.

Preferred embodiments of the formulation according to the present invention and other aspects of the present invention are described in the following description and the claims.

### BRIEF DESCRIPTION OF THE DRAWINGS

FIG. 1 schematically illustrates the general architecture of a conventional organic photovoltaic device.

FIG. 2 schematically illustrates an exemplary architecture of an organic photovoltaic device.

FIG. 3 shows a comparison of the transmission properties of OPV devices with and without a bi-layer comprising an organic buffer layer and a silicon oxide layer.

FIG. 4 shows the modelled transmission enhancement upon addition of a bi-layer comprising an organic buffer layer and a silicon oxide layer.

FIG. 5 shows a comparison of the photovoltaic response of OPV devices with and without a bi-layer comprising an organic buffer layer and a silicon oxide layer.

FIG. 6 illustrates the effect of the silicon oxide (SiO₂) layer thickness on the transmission and reflection properties at 550 nm.

### DETAILED DESCRIPTION OF THE INVENTION

For a more complete understanding of the present invention, reference is now made to the following description of the illustrative embodiments thereof:

### Semi-Transparent Cathode Layer Stack

In a first embodiment, the present invention relates to a semi-transparent cathode layer stack for a organic photovoltaic device comprising an organic buffer layer deposited over a semi-transparent metal cathode and a silicon dioxide (SiO₂) layer provided over the organic buffer layer, wherein the refractive index of the silicon dioxide layer is lower than the refractive index of the buffer layer, and wherein the thickness of the silicon dioxide layer is less than 100 nm.

The use of said semi-transparent cathode layer stack leads to an enhancement in the transmission in the visible region for semi-transparent OPV devices without impacting the power conversion efficiency of the device. Accordingly, the number of potential materials which may be effectively used as semi-transparent cathode material is increased.

From the viewpoint of further optimized transmission/reflection properties, it is preferable that the thickness of the silicon dioxide layer is in the range of from 20 to 70 nm, more preferably in the range of from 30 to 60 nm.

The terms “deposited over” or “provided over”, as used herein, mean that the respective layers may be formed directly in contact with the underlying layer or with intermediate layers inbetween. In a preferred embodiment, the organic buffer layer is in direct contact with the silicon dioxide layer and/or the semi-transparent metal cathode. More preferably, the organic buffer layer is in direct contact with both the silicon dioxide layer and the semi-transparent metal cathode.

The present invention essentially requires that the refractive index of the silicon dioxide layer is lower than the refractive index of the buffer layer. In a preferred embodiment, the organic buffer layer has a refractive index higher than 1.5, preferably higher than 1.6. More preferably, the organic buffer layer has a refractive index of 1.8 or higher. Preferably, the silicon dioxide layer has a refractive index of 1.5 or less.

The semi-transparent metal cathode is a semi-transparent thin metal or metal containing film, wherein the metal may be suitably chosen by the skilled artisan. As examples for metals, silver (Ag), gold (Au) or aluminum (Al) may be mentioned. It is preferable in terms of a favourable balance of optical and conductive properties that the semi-transparent metal cathode comprises Ag. More preferably, the semi-transparent metal cathode is a thin film consisting of Ag.

It is preferable that the semi-transparent metal cathode has a thickness in the range of 1 to 50 nm, more preferably in the range of 5 to 25 nm, even more preferably in the range of 10 to 20 nm, in order to assure that both high transmission and good conduction are achieved.

The material constituting the organic buffer layer is not particularly limited as long as its refractive index is higher than that of the silicon oxide layer and as long as it does not negatively impact the transparency of the cathode stack. The material may be suitably chosen by the skilled artisan from buffer materials conventionally used in the protection of organic electronic devices (e.g. OLEDs) from sputter damage. As examples thereof, bathocupuroin (BCP), bathophenanthroline (Bphen) (each of which may be doped with metals) and phthalocyanines may be mentioned. The buffer layer may also be an organic buffer layer as described in US 2012/0211782 A1, for example.

Preferably, the organic buffer layer has a thickness in the range of 2 to 100 nm, more preferably in the range of 5 to 50 nm.

The organic buffer layer is typically formed by evaporation and thereby prevents the semi-transparent metal cathode layer from being damaged during subsequent formation of the silicon oxide layer by sputter techniques.

In a second embodiment, the present invention therefore also relates to a method of manufacturing a semi-transparent cathode layer stack comprising a silicon dioxide (SiO₂) layer, an organic buffer layer, a semi-transparent metal cathode and an organic buffer layer, the method comprising: evaporating the organic buffer layer onto the semi-transparent metal cathode, and depositing the silicon dioxide layer on the organic buffer layer by a sputtering method, wherein the refractive index of the silicon dioxide layer is lower than the refractive index of the buffer layer, and wherein the thickness of the silicon dioxide layer is less than 100 nm.

### Organic Photovoltaic Devices and Their Applications

In a third embodiment, the present invention relates to an organic photovoltaic device comprising a semi-transparent cathode layer stack according to the first embodiment described above.

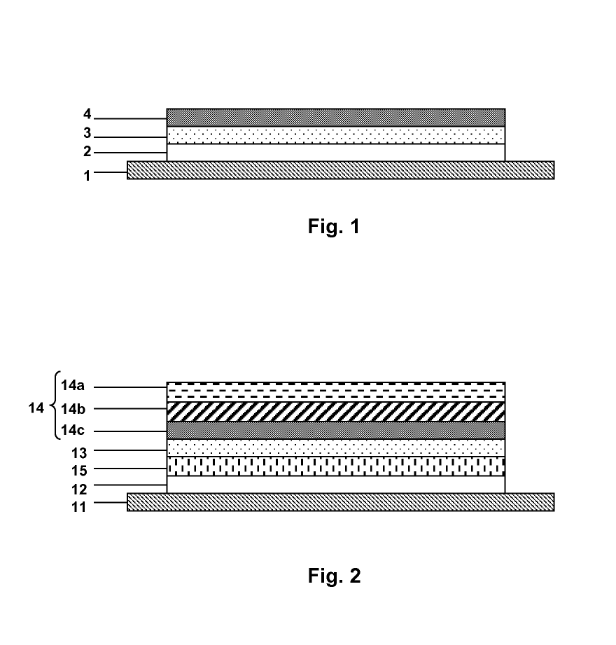

The general architecture of a prior art organic photovoltaic device is schematically depicted in FIG. 1. Herein, an anode 2 usually consisting of a high work-function material is deposited onto a substrate 1 made of a material transparent to visible light. Typical anode materials include conductive metal oxides, such as indium tin oxide (ITO) and indium zinc oxide (IZO), aluminum zinc oxide (AlZnO), and metals (e.g. gold), while glass or plastics are conventionally used as substrate materials. Between the anode 2 and the cathode 4, which is usually made of metals (e.g. Ag, Ag:Mg) or metal oxides, a photoactive layer 3 is formed.

The photoactive layer 3 typically comprises a bulk heterojunction formed by the presence of a p-type and an n-type organic semiconductor (OSC).

The p-type OSC is not particularly limited and may be appropriately selected from standard electron donating materials that are known to the person skilled in the art and are described in the literature, including organic polymers, oligomers and small molecules.

The n-type OSC is also not particularly limited and may be suitably selected from electron accepting materials known to the skilled artisan and may consist of a mixture of a plurality of electron accepting materials. As examples thereof, n-type conjugated polymers, fullerenes and fullerene derivatives may be mentioned.

Further layers may be present in the device, such as e.g. electron blocking layers (EBL), hole-transporting layers (HTL), hole-injecting layers (HIL), electron-injecting layers (EIL), exciton-blocking layer (XBL), spacer layers, connecting layers and hole-blocking layers (HBL), for example.

In the organic photovoltaic device of the present invention, the cathode comprises an organic buffer layer deposited over a semi-transparent metal cathode and a silicon dioxide (SiO₂) layer provided over the organic buffer layer, wherein the refractive index of the silicon dioxide layer is lower than the refractive index of the buffer layer, and wherein the thickness of the silicon dioxide layer is less than 100 nm.

An illustrative example of the organic photovoltaic device of the present invention is depicted in FIG. 2. Here, the anode 12 is deposited onto a substrate 11 made of a material transparent to visible light. A hole transport layer 16 is formed on the anode and a photoactive layer 13 is formed on the hole transport layer 16, typically by solution deposition techniques such as spin coating. The cathode 14 is a stack formed by subsequently depositing onto the photoactive layer 13 a semi-transparent metal cathode layer 14c (which is typically formed by evaporation, e.g. when using Ag), an organic buffer layer 14b (which is likewise typically formed by evaporation techniques), and a silicon oxide (SiO₂) layer 14a (which is typically formed by sputtering methods).

It is to be noted that the device configuration of FIG. 2 is merely illustrative and does not intend to limit the present invention to the particular configuration. For example, it will be understood that the hole-transport layer 16 may be omitted and/or other layers may be present in the device, such as e.g. electron blocking layers (EBL), hole-injecting layers (HIL), electron-injecting layers (EIL), exciton-blocking layer (XBL), spacer layers, connecting layers and hole-blocking layers (HBL), for example.

The organic photovoltaic device preferably has an average transparency of at least 30%, more preferably at least 35%, even more preferably at least 40% across the visible range of wavelengths 400 nm to 650 nm.

In a fifth embodiment, the present invention relates to building material comprising the organic photovoltaic device according to the third embodiment described above.

The building material includes windows, roofs, curtain walls or fagades, for example. However, in order to take full advantage of the present invention, particularly in view of the favourably high transmission of the OPV device of the present invention, it is preferable that the building material is window glass.

In a fourth embodiment, the present invention relates to the use of the organic photovoltaic device according to the third embodiment in building-integrated photovoltaics or building-applied photovoltaics.

The term “building-integrated photovoltaics”, as used herein, denotes photovoltaic materials that are used to replace conventional building materials in parts of the building envelope such as the roof, skylights of facades, while the term “building-applied photovoltaics” refers to photovoltaic materials that are a retrofit, i.e. integrated into the building after construction is complete.

It will be appreciated that the preferred features specified above may be combined in any combination, except for combinations where at least some of the features are mutually exclusive.

### EXAMPLES

### Example 1

An organic photovoltaic device having the configuration shown in FIG. 2 was prepared, using a glass substrate and an indium-tin oxide (ITO) anode. A hole transport layer was spin coated onto the anode, and a photoactive layer comprising [6,6]-phenyl C₆₁-butyric acid (PCBM) as n-type organic semiconductor and poly(3-hexylthiophene) (P3HT) as a p-type organic semiconductor was spin coated onto the hole transport layer.

Thereafter, a thin Ag layer having a thickness of 17 nm was evaporated onto the photoactive layer. A 20 nm thick organic buffer layer (Novaled BH-5; refractive index n 1.8) was then evaporated onto the Ag layer. Finally, a silicon oxide (SiO₂) layer having a refractive index n of 1.5 was sputtered onto the organic buffer layer to a thickness of 50 nm.

### Comparative Example 1

An organic photovoltaic device has been prepared according to Example 1, with the exception that the organic buffer layer and the silicon oxide (SiO₂) layer have been omitted.

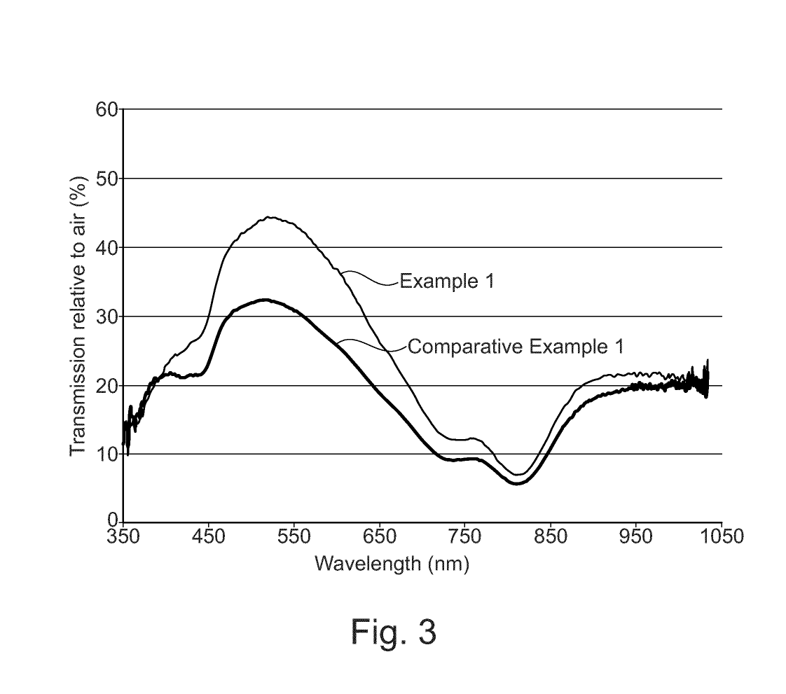

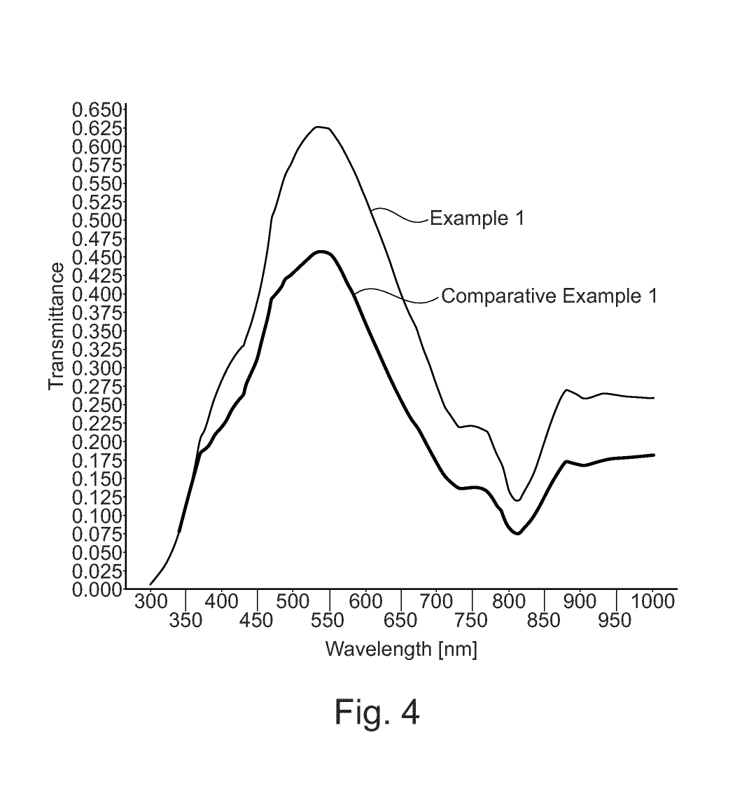

The wavelength-dependent transmission of the OPV devices of Example 1 and Comparative Example 1 has been measured relative to air. The corresponding experimentally measured and optical modelling spectra are shown in FIG. 3 and FIG. 4, respectively. FIGS. 3 and 4 demonstrate that the transmission in the visible wavelength range of 400 to 650 nm is remarkably enhanced by the addition of the bi-layer stack including the organic buffer layer and the silicon oxide (SiO₂) layer (>40%) when compared to the thin silver only device (˜30% transmission).

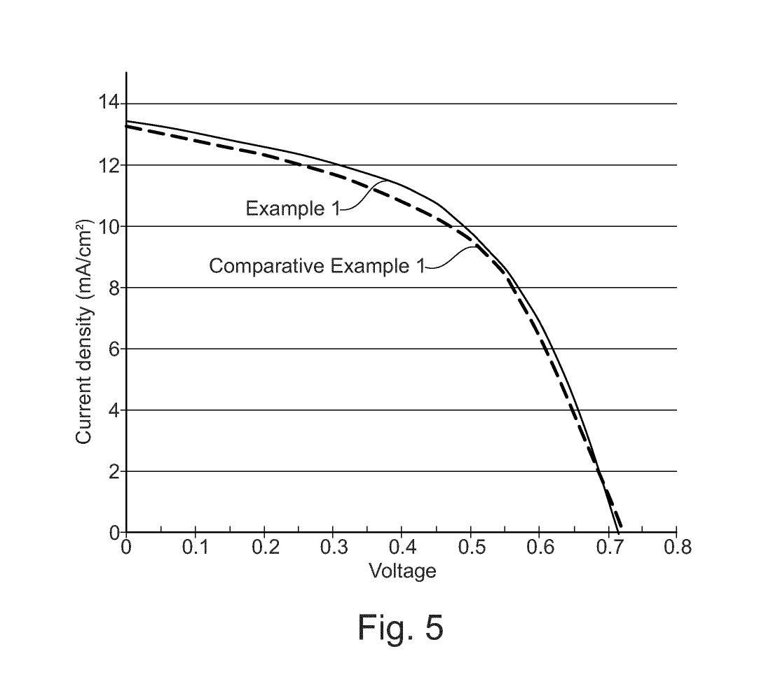

In FIG. 5, the results of the measurement of the photovoltaic response of the OPV devices of Example 1 and Comparative Example 1 are shown, which demonstrate that the OPV device transmission is enhanced without negatively affecting the power conversion efficiency.

### Example 2

The transmission and reflection properties at 550 nm in dependence of silicon oxide (SiO₂) layer thickness have been studied by optical modelling on the basis of an organic photovoltaic device having the following configuration (in order):

glass substrate//ITO (150 nm)//hole-injection layer (40 nm)//photoactive layer (160 nm)//thin Ag layer (12 nm)//organic buffer layer (20 nm)//silicon oxide layer

As the photoactive layer, a blend of PCBM and a p-type organic semiconductor according to structural formula (1) was used:

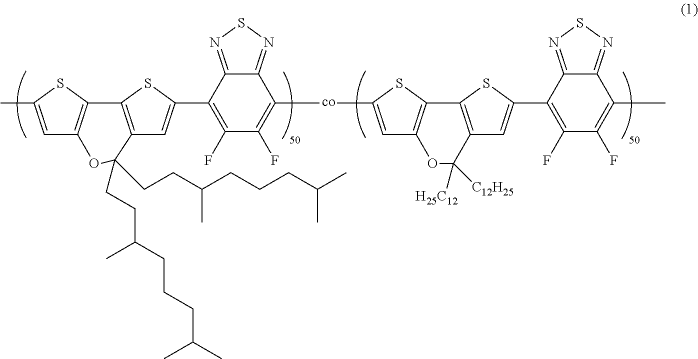

Novaled BH-5 (refractive index n ≈1.8) was used as organic buffer layer material, and CA2429 (commercially available from Solvay/Plextronics Inc.) as the material for the hole-injection layer.

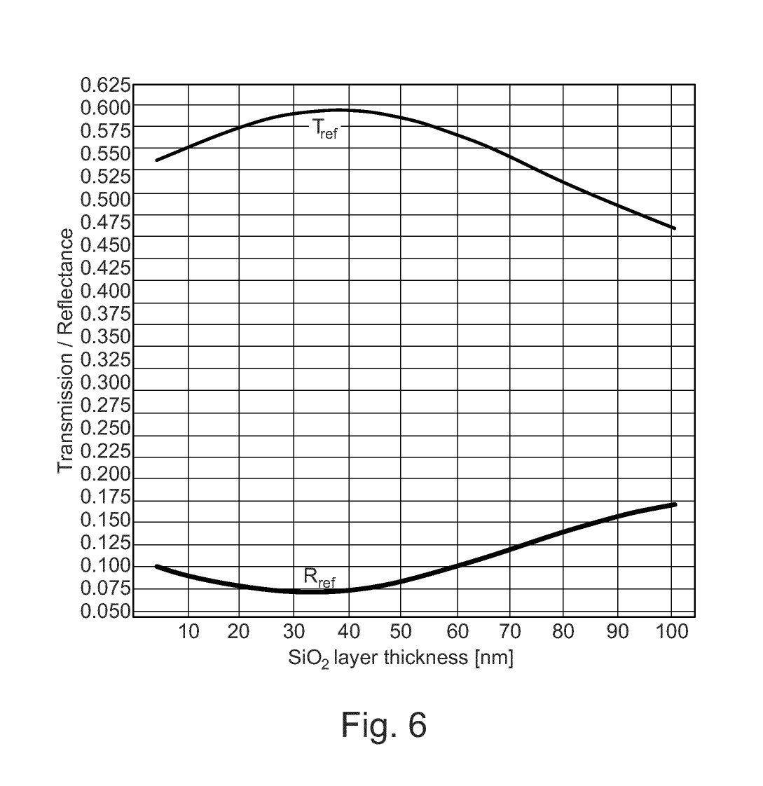

The results shown in FIG. 6 indicate that the transmission/reflection properties are further improved by adjusting the thickness of the silicon oxide layer to a range of from about 20 to about 70 nm.

### Example 3 and Comparative Examples 2 to 4

The transmission properties at 550 nm and the short circuit current (J_{sc}) of devices having different configurations (using the same materials as in Example 2) have been studied in further detail.

The results are shown in the table below. Herein, X and —indicate that a layer is present or absent, respectively. The comparison between Example 3 and Comparative Example 4 demonstrates that the presence of the silicon oxide layer remarkably improves the transmission, while retaining a high short circuit current. While Comparative Examples 2 and 3 exhibit favourable transmission properties, their short circuit current is comparatively poor, thereby leading to low power conversion efficiencies:

| | | | Comparative | Comparative | Comparative |
|---|---|---|---|---|---|
| | | Example 3 | Example 2 | Example 3 | Example 4 |
| configuration | ITO anode | X | X | X | X |
| | (150 nm) | | | | |
| | hole-injection | X | X | X | X |
| | layer (40 nm) | | | | |
| | photoactive | X | X | X | X |
| | layer (160 nm) | | | | |
| | Ag layer (12 nm) | X | — | — (air) | X |
| | organic buffer | X | X | — | X |
| | layer (20 nm) | | | | |
| | silicon oxide | X | X | — | — |
| | (SiO₂) layer | | | | |
| | (50 nm) | | | | |

| | | | | |
|---|---|---|---|---|
| transmission at 550 nm (%) | 63.0 | 67.0 | 65.0 | 56.0 |
| short circuit current J_{SC} (mA/cm²) | 14.1 | 12.7 | 13.1 | 14.7 |

Accordingly, it has been shown that the use of the cathode layer stack according to the present invention allows maximizing the transmission properties without substantial loss in photovoltaic performance.

Once given the above disclosure, many other features, modifications, and improvements will become apparent to the skilled artisan.

### REFERENCE NUMERALS

1/11: substrate layer
2/12: anode
3/13: photoactive layer
4: cathode
14: cathode layer stack
14a: silicon oxide (SiO₂) layer
14b: organic buffer layer
14c: semi-transparent metal cathode layer
15: hole transport layer

1. A semi-transparent cathode layer stack (14) for a organic photovoltaic device comprising an organic buffer layer (14b) deposited over a semi-transparent metal cathode (14c) and a silicon dioxide (SiO₂) layer (14a) provided over the organic buffer layer (14b),
wherein the refractive index of the silicon dioxide layer (14a) is lower than the refractive index of the buffer layer (14b), and
wherein the thickness of the silicon dioxide layer (14a) is less than 100 nm.

2. The semi-transparent cathode layer stack according to claim 1, wherein the thickness of the silicon dioxide layer (14a) is in the range of from 20 to 70 nm.

3. The semi-transparent cathode layer stack according to claim 1, wherein the thickness of the silicon dioxide layer (14a) is in the range of from 30 to 60 nm.

4. The semi-transparent cathode layer stack according to claim 1, wherein the organic buffer layer (14b) is in direct contact with the silicon dioxide layer (14a) and/or the semi-transparent metal cathode (14c).

5. The semi-transparent cathode layer stack according to claim 1, wherein the organic buffer layer (14b) has an refractive index higher than 1.5, preferably higher than 1.6.

6. The semi-transparent cathode layer stack according to claim 1, wherein the semi-transparent metal cathode (14c) has a thickness in the range of 1 to 50 nm, preferably in the range of 5 to 25 nm.

7. The semi-transparent cathode layer stack according to claim 1, wherein the organic buffer layer (14b) has a thickness in the range of 2 to 100 nm, preferably in the range of 5 to 50 nm.

8. The semi-transparent cathode layer stack according to claim 1, wherein the semi-transparent metal cathode (14c) comprises Ag.

9. The semi-transparent cathode layer stack according to claim 1, wherein the organic buffer layer (14b) is deposited over the semi-transparent metal cathode (14c) by evaporation and the silicon dioxide (SiO₂) layer (14a) is deposited over the organic buffer layer (14b) by a sputtering method.

10. Method of manufacturing a semi-transparent cathode layer stack (14) comprising a silicon dioxide (SiO₂) layer (14a), an organic buffer layer (14b), a semi-transparent metal cathode (14c) and an organic buffer layer (14b), the method comprising:
evaporating the organic buffer layer (14b) onto the semi-transparent metal cathode (14c), and
depositing the silicon dioxide (SiO₂) layer (14c) on the organic buffer layer (14b) by a sputtering method,
wherein the refractive index of the silicon dioxide layer (14a) is lower than the refractive index of the buffer layer (14b), and
wherein the thickness of the silicon dioxide layer (14a) is less than 100 nm.

11. Organic photovoltaic device comprising a semi-transparent cathode layer stack according to claim 1.

12. Building material comprising an organic photovoltaic device according to claim 10.

13. Building material according to claim 12, wherein the building material is window glass.

14. Use of the organic photovoltaic device according to claim 11 in building-integrated photovoltaics or building-applied photovoltaics.
